(19) United States
(12) Patent Application Publication
(10) Pub. No.: US 2021/0175089 A1
(43) Pub. Date: Jun. 10, 2021

(54) ETCHING METHOD

(71) Applicant: SCREEN Holdings Co., Ltd., Kyoto (JP)

(72) Inventors: Kazuki NISHIHARA, Kyoto-shi (JP); Masaki INABA, Kyoto-shi (JP)

(21) Appl. No.: 17/089,285

(22) Filed: Nov. 4, 2020

(30) Foreign Application Priority Data
Dec. 4, 2019 (JP) 2019-219595

(51) Int. Cl. H01L 21/311

(52) U.S. Cl. CPC H01L 21/31116

(57) ABSTRACT

An etching method is a method for etching a target film formed on a substrate, using steam and hydrogen fluoride gas. The etching method includes a substrate placing step, a steam supplying step, and a hydrogen fluoride gas supplying step. In the substrate placing step, the substrate is placed in a chamber. In the steam supplying step, the steam is supplied to the chamber. In the hydrogen fluoride gas supplying step, the hydrogen fluoride gas is supplied to the chamber. In the steam supplying step, a flow rate of the steam is controlled so that a pressure of the steam on a surface of the substrate is lower than a saturated steam pressure.

### BACKGROUND OF THE INVENTION

### Field of the Invention

The present disclosure relates to an etching method.

### Description of the Background Art

Substrate processing units each supplying hydrogen fluoride gas and steam to a substrate and etching a silicon oxide film formed on the substrate have been conventionally proposed (for example, Japanese Patent Application Laid-Open No. 2019-114628).

In recent years, patterns formed on the substrates have increasingly been miniaturized, and the aspect ratios have also been increased. Supplying hydrogen fluoride gas and steam to such a substrate with a miniaturized pattern and a higher aspect ratio can etch an oxide film on the substrate. However, the steam may be liquefied on the patterned surface during the etching. When the steam is liquefied between patterns, its high surface tension may cause the patterns to be attracted to each other and collapse.

### SUMMARY

An aspect of this disclosure is a method for etching a target film formed on a substrate, using steam and hydrogen fluoride gas, and the method includes: a substrate placing step of placing the substrate in a chamber; a steam supplying step of supplying the steam to the chamber; and a hydrogen fluoride gas supplying step of supplying the hydrogen fluoride gas to the chamber. In the steam supplying step, a flow rate of the steam is controlled so that a pressure of the steam on a surface of the substrate is lower than a saturated steam pressure.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a side view schematically illustrating an example structure of an etching apparatus;

FIG. 2 is a flowchart illustrating an example procedure for processing (etching) a substrate in the etching apparatus;

FIG. 3 is a cross-sectional view schematically illustrating an example structure of a substrate;

FIG. 4 is a graph illustrating temperatures of the substrate and pressures in a chamber;

FIG. 5 is a side view schematically illustrating another example structure of the etching apparatus; and

FIG. 6 is a flowchart illustrating another example procedure for processing (etching) the substrate in the etching apparatus.

### DESCRIPTION OF THE PREFERRED EMBODIMENTS

Hereinafter, Embodiments will be described with reference to the accompanying drawings. The constituent elements described in these Embodiments are mere exemplification, and are not intended to limit the scope of the disclosure. It should be noted that dimensions and the number of components in the drawings are shown in exaggeration or simplified as appropriate for the sake of easier understanding.

Unless otherwise noted, the expressions indicating relative or absolute positional relationships (e.g., “in one direction”, “along one direction”, “parallel”, “orthogonal”, “central”, “concentric”, and “coaxial”) include those exactly indicating the positional relationships and those where an angle or a distance is relatively changed within tolerance or to the extent that similar functions can be obtained. Unless otherwise noted, the expressions indicating equality (e.g., “same”, “equal”, “uniform”, and “homogeneous”) include those indicating quantitatively exact equality and those in the presence of a difference within tolerance or to the extent that similar functions can be obtained. Unless otherwise noted, the expressions indicating shapes (e.g., “rectangular” or “cylindrical”) include those indicating geometrically exact shapes and those indicating, for example, roughness or a chamfer to the extent that similar advantages can be obtained. An expression “comprising”, “including”, or “having” a certain constituent element is not an exclusive expression for excluding the presence of the other constituent elements. An expression “at least one of A, B, and C” involves only A, only B, only C, arbitrary two of A, B, and C, and all of A, B, and C.

### Embodiment 1

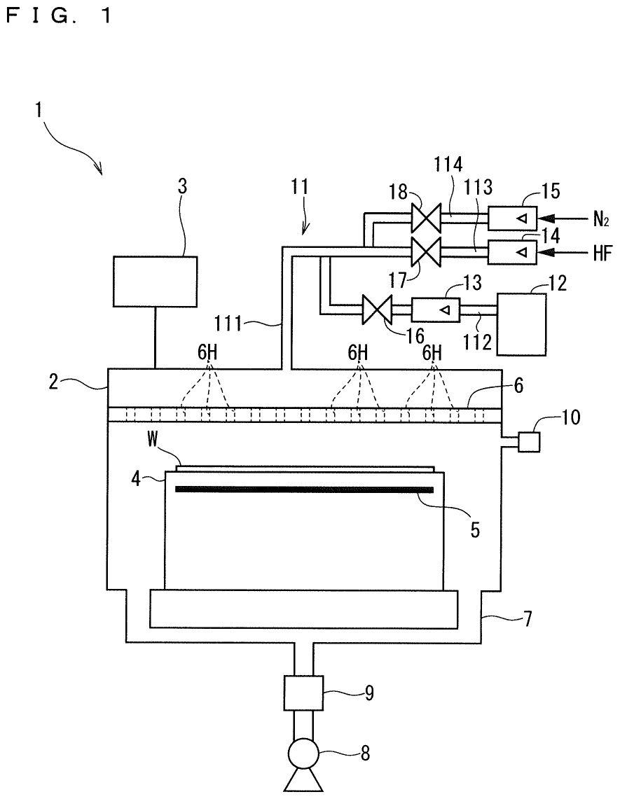

FIG. 1 is a side view schematically illustrating an example structure of an etching apparatus 1. The etching apparatus 1 is a single wafer etching apparatus that etches substrates W such as a semiconductor wafer one by one, for example, a vapor phase etching apparatus without using plasma. The etching apparatus 1 is applicable to a part of apparatuses that manufacture semiconductor devices. The substrate W is not necessarily a substrate for the semiconductor devices. Examples of the substrate W include a liquid crystal display substrate, a plasma display substrate, an organic electro-luminescent (EL) substrate, a field emission display (FED) substrate, an optical display substrate, a magneto-optical disk substrate, a photomask substrate, and a solar cell substrate.

The etching apparatus 1 includes a chamber 2 and a controller 3. The chamber 2 has a hollow shape allowing the substrate W to be accommodated inside. The internal space of the chamber 2 is a treatment space for applying predetermined treatment on the substrate W. The controller 3 controls operations of the constituent elements included in the etching apparatus 1, such as opening and closing of valves (to be described later).

The chamber 2 houses a substrate holder 4, a heating mechanism 5 for the substrate W, a gas distribution plate 6, and a pressure sensor 10.

The substrate holder 4 holds the substrate W in an approximately horizontal attitude in the chamber 2. The “horizontal attitude” means a state where the substrate W is parallel to the horizon plane. A transfer system that is not illustrated transfers the substrate W from outside into the chamber 2, and places the substrate W on the substrate holder 4. The substrate holder 4 may suck and hold the substrate W or sandwich an outer edge of the substrate W between a plurality of chuck pins. The substrate holder 4 need not necessarily hold the substrate W and may simply support the substrate W. In other words, the substrate holder 4 may be a mount on which the substrate W is mounted.

The heating mechanism 5 heats the substrate W held by the substrate holder 4. In the example of FIG. 1, the heating mechanism 5 is built in the substrate holder 4. The heating mechanism 5 is, for example, a resistance-heated electric heater. The heating mechanism 5 may include, for example, a lamp instead of being an electric heater. The lamp may irradiate the substrate W with infrared rays to control the temperature of the substrate W at a predetermined temperature.

The gas distribution plate 6 is placed above the substrate holder 4 in the chamber 2. The gas distribution plate 6 is shaped like a plate horizontally extending in the chamber 2. A plurality of openings 6H pierced in the thickness direction are horizontally formed in a dispersed manner in the gas distribution plate 6.

An exhaust pipe 7 is connected to the chamber 2. In the example of FIG. 1, the exhaust pipe 7 is connected to the bottom of the chamber 2 while communicating with the chamber 2. A vacuum pump 8 is also connected to the exhaust pipe 7. The vacuum pump 8 depressurizes the chamber 2 by sucking gas in the chamber 2 through the exhaust pipe 7.

An Auto Pressure Controller (APC) valve 9 is interposed in the exhaust pipe 7. The APC valve 9 adjusts an exhaust flow rate of the gas in the chamber 2 by adjusting the degree of opening of the exhaust pipe 7. This can adjust the pressure in the chamber 2. The pressure sensor 10 is joined to the chamber 2 to detect the pressure in the chamber 2. The pressure sensor 10 outputs, to the controller 3, an electrical signal indicating the detected pressure in the chamber 2. The controller 3 controls the APC valve 9 to adjust the pressure in the chamber 2 so that the pressure detected by the pressure sensor 10 falls within a predetermined pressure range.

After the substrate W is held by the substrate holder 4, the vacuum pump 8 is activated to start the vacuuming in the chamber 2. Although the vacuum pump 8 is described as a means that depressurizes the chamber 2 in Embodiment 1, the means is not limited to the vacuum pump 8. The depressurizing is possible through, for example, a factory utility exhaust system. In other words, a specific structure of an exhaust part that exhausts the gas in the chamber 2 can be appropriately changed.

A gas supply pipe 11 is connected to the chamber 2. In the example of FIG. 1, the gas supply pipe 11 is connected to the top of the chamber 2 while communicating with the chamber 2. In the example of FIG. 1, the gas supply pipe 11 includes a common pipe 111 and branch pipes 112 to 114. One end of the common pipe 111 is connected to the top of the chamber 2. The branch pipe 112 connects the common pipe 111 to a vaporizer 12. The vaporizer 12 stores water for generating steam. A steam flow rate controller 13 is interposed in the branch pipe 112. The steam flow rate controller 13 is a generally-called mass flow controller, and adjusts the supply flow rate of the steam supplied to the chamber 2.

An open/close valve 16 is also interposed in the branch pipe 112. Opening this open/close valve 16 supplies the steam vaporized by the vaporizer 12 to the chamber 2 through the gas supply pipe 11 (the branch pipe 112 and the common pipe 111). A nitrogen gas supply pipe that is not illustrated supplies nitrogen gas to the vaporizer 12 as carrier gas. The nitrogen gas carries the steam vaporized in the vaporizer 12 into the chamber 2 through the gas supply pipe 11.

The branch pipe 113 connects the common pipe 111 to a hydrogen fluoride (HF) supply source (not illustrated). A HF gas flow rate controller 14 is interposed in the branch pipe 113. The HF gas flow rate controller 14 is a generally-called mass flow controller, and controls the supply flow rate of the HF gas supplied to the chamber 2. An open/close valve 17 is interposed in the branch pipe 113. Opening this open/close valve 17 supplies the HF gas to the chamber 2 through the gas supply pipe 11 (the branch pipe 113 and the common pipe 111). The HF gas flow rate controller 14 adjusts the supply flow rate of the HF gas. The steam and the HF gas are simultaneously supplied to the chamber 2.

The branch pipe 114 connects the common pipe 111 to a nitrogen supply source (not illustrated). An open/close valve 18 and a nitrogen gas flow rate controller 15 are interposed in the branch pipe 114. Opening this open/close valve 18 supplies nitrogen gas to the chamber 2 through the gas supply pipe 11 (the branch pipe 114 and the common pipe 111). The nitrogen gas flow rate controller 15 adjusts the supply flow rate of the nitrogen gas. The nitrogen gas is supplied to the chamber 2 to adjust the pressure in the chamber 2 or purge gas from the chamber 2 after the etching under reduced pressure.

The steam (including nitrogen gas functioning as carrier gas) and the HF gas that are supplied to the chamber 2 through the gas supply pipe 11 that is connected in communication with the internal space of the chamber 2 reach the substrate W through the gas distribution plate 6. Specifically, mixed gas of the steam (including nitrogen gas functioning as carrier gas) and the HF gas that are supplied above the gas distribution plate 6 in the chamber 2 moves below the gas distribution plate 6 through the plurality of openings 6H of the gas distribution plate 6, and is evenly supplied to the substrate W. The opening 6H has an interior diameter of, for example, 0.1 mm. Furthermore, the interval between the adjacent openings 6H is, for example, 5 mm. The interior diameter and the interval of the openings 6H are not limited to these. Although only the gas distribution plate 6 is placed in the chamber 2 in the example of FIG. 1, a plurality of the gas distribution plates 6 may be stacked as multiple vertical layers. When the necessity to evenly subject the substrate W to the steam and the HF gas that are supplied to the chamber 2 is low or when the steam and the HF gas can be rectified through a structure except for the gas distribution plate 6, the gas distribution plate 6 is unnecessary.

When the steam and the HF gas flow through the surface of the silicon oxide film of the substrate W, the silicon oxide film is etched. A main contribution of bifluoride ion (HF₂⁻) to the etching of this silicon oxide film is known. This HF₂⁻ is generated by reaction of the HF gas with the steam (H₂O).

The controller 3 controls the heating mechanism 5, the vacuum pump 8, the APC valve 9, the pressure sensor 10, the steam flow rate controller 13, the HF gas flow rate controller 14, the nitrogen gas flow rate controller 15, and the open/close valves 16 to 18.

The controller 3 is an electronic circuit device, and may include, for example, a data processor and a storage. The data processor may be, for example, an arithmetic processing unit such as a central processing unit (CPU). The storage may include a non-transitory recording medium (e.g., a Read Only Memory (ROM) or hard disk) and a transitory recording medium (e.g., a Random Access Memory (RAM)). The non-transitory recording medium may store, for example, a program for defining processes to be executed by the controller 3. The data processor executes this program, so that the controller 3 can execute the processes defined in the program. Obviously, a hardware circuit such as a logic circuit may execute a part or all the processes to be executed by the controller 3.

The supply flow rates of the HF gas, the steam, and the nitrogen gas for etching the silicon oxide film formed on the substrate W are, for example, several thousand sccm or less (e.g., 3,000 sccm), several thousand sccm or less (e.g., 2,000 sccm), and several tens of thousands sccm or less (e.g., 10,000 sccm), respectively. These supply flow rates may be appropriately changed.

The controller 3 adjusts the degree of opening of the APC valve 9 so that the pressure detected by the pressure sensor 10 falls within the predetermined pressure range. This appropriately adjusts the pressure in the chamber 2. The pressure in the chamber 2 is maintained at, for example, 5 to 80 Torr during the treatment on the substrate W.

According to Embodiment 1, the controller 3 controls, for example, the supply flow rate of the steam so that the pressure of the steam on the surface of the substrate W placed in the chamber 2 is lower than a saturated steam pressure. Specifically, the pressure of the steam on the surface of the substrate W can be controlled by the supply flow rates of the various gases to be supplied to the chamber 2 and the exhaust flow rates of the gases exhausted from the chamber 2.

As long as the pressure of the steam on the surface of the substrate W can be maintained lower than the saturated steam pressure, the probability that the steam is liquefied and adhered to the surface of the substrate W can be reduced. Thus, the probability that the surface tension of water collapses the patterns of the substrate W can be reduced. Ideally, liquefaction of the steam and a collapse of the patterns caused by the liquefaction can be prevented.

### [Procedure for Processing Substrate]

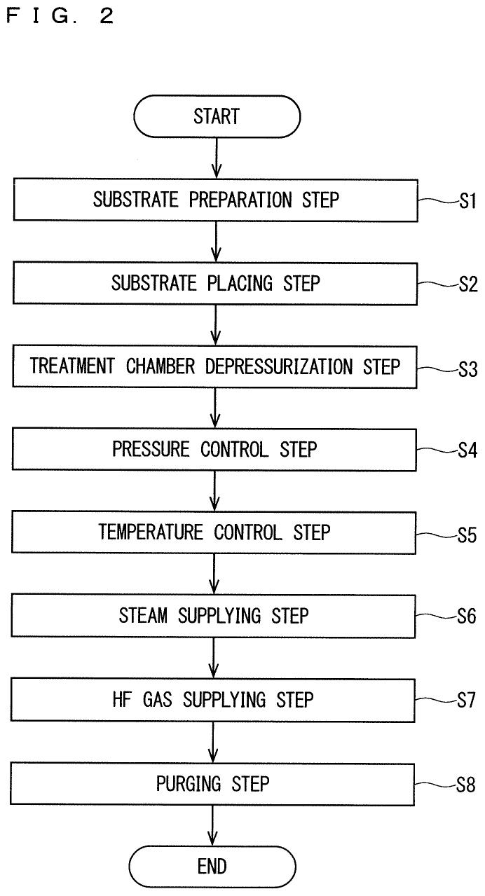

FIG. 2 illustrates an example procedure for processing (etching) a substrate in the etching apparatus 1 according to Embodiment 1. The etching to be described below is applicable to a part of the processes for manufacturing semiconductor devices.

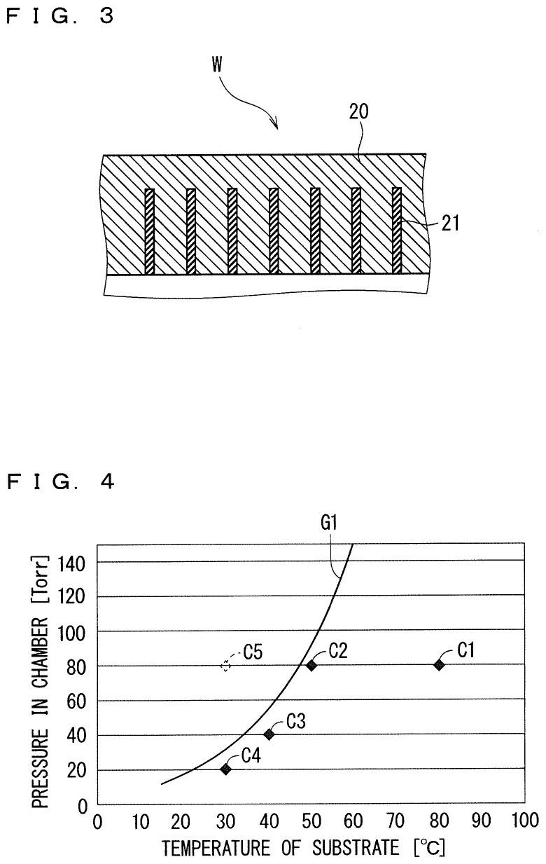

First, the substrate W to be etched is prepared (Step S1: a preparation step). A silicon oxide film that is an example target film and a silicon nitride film that is an example lower film of the silicon oxide film are formed on the upper surface of the substrate W. FIG. 3 is a cross-sectional view schematically illustrating an example structure of a part of the substrate W. FIG. 3 is a cross-sectional view of the substrate W. In the example of FIG. 3, a silicon nitride film 21 is formed in a pattern on the upper surface of the substrate W, and a silicon oxide film 20 is formed to cover the silicon nitride film 21. The pattern width and the interval between the patterns of the silicon nitride film 21 are, for example, approximately several tens nm (e.g., 30 nm), and its aspect ratio ranges, for example, from 10 to 50. The silicon oxide film 20 covers the upper surface of the silicon nitride film 21 while filling in the patterns of the silicon nitride film 21.

A method for forming the silicon oxide film 20 and the silicon nitride film 21 can be any method. For example, the silicon oxide film 20 is formed by spin-on dielectric (SOD), and the silicon nitride film 21 is formed by plasma chemical vapor deposition (CVD). Here, the silicon oxide film 20 is removed by etching to leave the silicon nitride film 21.

After the substrate W is prepared in Step S1, the transfer system that is not illustrated transfers the substrate W into the chamber 2, and places the substrate W on the substrate holder 4 (Step S2: a substrate placing step).

After the substrate W is placed on the substrate holder 4, the controller 3 controls the vacuum pump 8 to pump out the chamber 2 to a high vacuum (Step S3: a treatment chamber depressurization step). The degree of depressurization is appropriately determined according to the capacity of the vacuum pump 8 to be used and the allowed depressurization time. Depressurizing the chamber 2 as much as possible can exhaust the atmosphere in the chamber 2 as much as possible, and increase the cleanliness of the chamber 2.

Once the chamber 2 is pumped out to a high vacuum, the controller 3 supplies nitrogen gas to the chamber 2 by opening the open/close valve 18. Furthermore, the controller 3 controls the nitrogen gas flow rate controller 15 to adjust the supply flow rate of the nitrogen gas and adjust the degree of opening of the APC valve 9, based on the pressure detected by the pressure sensor 10. Through these adjustments, the controller 3 adjusts the pressure in the chamber 2 within a predetermined pressure range (Step S4: a pressure control step). The pressure value in the chamber 2 will be described later in detail.

Furthermore, the controller 3 controls the heating mechanism 5 to control the temperature of the substrate W at a predetermined temperature (Step S5: a temperature control step). The controller 3 may start controlling (heating) the temperature of the substrate holder 4, for example, almost simultaneously when the chamber 2 starts to be depressurized in Step S3.

The temperature of the substrate W affects a selection ratio of the silicon oxide film 20 to the silicon nitride film 21, which will be described later in detail. This selection ratio corresponds to a ratio of an etch rate of the silicon oxide film 20 to an etch rate of the silicon nitride film 21. In the temperature control step of Step S5, the temperature of the substrate W is adjusted within a predetermined temperature range so that the selection ratio falls within a predetermined range. The specific temperature value of the substrate W will be described later in detail.

When the temperature of the substrate W falls within the predetermined temperature range after start of the temperature control step of Step 5, the controller 3 supplies steam (including carrier gas) to the chamber 2 by opening the open/close valve 16 (Step S6: a steam supplying step). Here, the controller 3 controls the steam flow rate controller 13 to adjust the supply flow rate of the steam within a predetermined flow rate range. This supply flow rate of the steam affects the etch rate of the silicon oxide film 20 and liquefaction of the steam, which will be described later in detail. Thus, the controller 3 controls the supply flow rate of the steam so that the silicon oxide film 20 can be etched at a predetermined etch rate and the pressure of the steam is lower than a saturated steam pressure.

After a lapse of a first predetermined time after start of the steam supplying step in Step S6, the controller 3 supplies the HF gas to the chamber 2 by opening the open/close valve 17 (Step S7: a hydrogen fluoride (HF) gas supplying step). This supplies both of the steam and the HF gas to the chamber 2. The mixed gas of the steam and the HF gas that are supplied to the chamber 2 almost evenly comes in contact with the entire surface of the substrate W through the plurality of openings 6H formed in the gas distribution plate 6. Here, the silicon oxide film 20 that is a target film is selectively etched with respect to the silicon nitride film 21 using the steam and the HF gas (etching). In this etching, nitrogen gas may be appropriately supplied to the chamber 2 by opening the open/close valve 18.

After a lapse of a second predetermined time appropriate for removing the target film after start of the etching, the controller 3 stops supplying the HF gas and the steam by closing the open/close valves 16 and 17. This ends the substantial etching.

After a lapse of a third predetermined time since stopping the supply of the steam and the HF gas, the controller 3 purges gas from the chamber 2 using nitrogen gas (Step S8: a purging step). Here, the controller 3 controls the nitrogen gas flow rate controller 15 to adjust the supply flow rate of the nitrogen gas. Consequently, the controller 3 purges gas from the chamber 2 under reduced pressure using the nitrogen gas to restore atmospheric pressure in the chamber 2 and allow the substrate W to be transferred out of the substrate holder 4. The transfer system that is not illustrated appropriately transfers the transferable substrate W from the substrate holder 4.

### [Explanation on Selective Etching]

Next, etching conditions for selectively etching the silicon oxide film 20 with respect to the silicon nitride film 21 will be described. The etching conditions include the temperature of the substrate W, the supply flow rates of the HF gas, the nitrogen gas, and the steam, and the pressure in the chamber 2.

The Applicant conducted an experiment aimed at measuring etch amounts of a silicon oxide film and a silicon nitride film under the different etching conditions. Specifically, a first substrate on the entire upper surface of which a silicon oxide film was formed and a second substrate on the entire upper surface of which a silicon nitride film was formed were etched for the same processing time, and the etch amounts thereof were measured. As the etching conditions, the supply flow rates of the HF gas, the steam, and the nitrogen gas were 2,000 sccm, 3,000 sccm, and 10,000 sccm, respectively. The temperature of the substrate W and the pressure in the chamber 2 were varied. The heating mechanism 5 adjusts the temperature of the substrate W. The exhaust part adjusts the pressure in the chamber 2 by controlling the exhaust flow rate of the gas from the chamber 2.

FIG. 4 is a graph illustrating the etching conditions. In FIG. 4, the horizontal axis represents the temperature of the substrate W, and the vertical axis represents the pressure in the chamber 2. In the example of FIG. 4, a saturated steam pressure curve G1 of water is also shown. In FIG. 4, the first conditions C1 (80° C., 80 Torr), the second conditions C2 (50° C., 80 Torr), the third conditions C3 (40° C., 40 Torr), and the fourth conditions (30° C., 20 Torr) C4 are plotted with black rhombi.

The result of the etching on the first substrate and the second substrate under the conditions C1 to C4 is indicated in the following table.

TABLE 1

| | ETCH AMOUNT [nm] | | SELECTION |
|---|---|---|---|
| CONDITION | SiO₂ | SiN | RATIO |
| C1 | 2.0 | 4.2 | 0.5 |
| C2 | 197.4 | 7.9 | 24.9 |
| C3 | 158.5 | 1.7 | 92.6 |
| C4 | 82.9 | 0.6 | 128.3 |

Under the first conditions C1, the etch amounts of the silicon oxide film and the silicon nitride film were 2.0 nm and 4.2 nm, respectively. Here, the etch amount is represented by a difference in thickness between before and after the etching of each film. Since the processing times for the etching are the same, the etch amount is proportional to an etch rate. Thus, the selection ratio is approximately 0.5 (=2.0/4.2). In other words, the silicon nitride film that is a non-target film was etched deeper than the silicon oxide film that is a target film under the first conditions C1.

Under the second conditions C2, the etch amounts of the silicon oxide film and the silicon nitride film were 197.4 nm and 7.9 nm, respectively. Thus, the selection ratio is approximately 24.9. In other words, the silicon oxide film that is a target film was able to be etched deeper than the silicon nitride film that is a non-target film under the second conditions C2. This is because the lower the temperature of the substrate W is, the more probably the steam remains on the surface of the substrate W. In other words, the lower the temperature of the substrate W is, the longer the steam remains on the surface of the substrate W. Specifically, the more the steam remains on the surface of the silicon oxide film, the more the silicon oxide film can be etched by reaction between the HF gas and the steam. On the other hand, the more the steam remains on the surface of the silicon nitride film, the more etching of the silicon nitride film can be inhibited.

Under the third conditions C3, the etch amounts of the silicon oxide film and the silicon nitride film were 158.5 nm and 1.7 nm, respectively. Thus, the selection ratio is approximately 92.6. In other words, the silicon oxide film under the third conditions C3 can be etched at a selection ratio higher than that under the second conditions C2. This is because the lower the temperature of the substrate W is, the more probably the steam remains on the surface of the substrate W.

On the other hand, the etch amount (158.5 nm) of the silicon oxide film under the third conditions C3 is smaller than that (197.4 nm) of the silicon oxide film under the second conditions C2. In other words, the etch rate of the silicon oxide film under the third conditions C3 is lower than that under the second conditions C2. This is because the pressure (40 Torr) in the chamber 2 under the third conditions C3 is lower than that (80 Torr) in the chamber 2 under the second conditions C2. Specifically, since the chamber 2 is depressurized by increasing the exhaust flow rate of the gas from the chamber 2, the amounts of the steam and the HF gas in the chamber 2 that are necessary for etching are reduced.

Under the fourth conditions C4, the etch amounts of the silicon oxide film and the silicon nitride film were 82.9 nm and 0.6 nm, respectively. Thus, the selection ratio is approximately 128.3. In other words, the silicon oxide film under the fourth conditions C4 can be etched at a selection ratio higher than that under the third conditions C3. This is because the lower the temperature of the substrate W is, the more probably the steam remains on the surface of the substrate W.

On the other hand, the etch amount (82.9 nm) of the silicon oxide film under the fourth conditions C4 is smaller than that (158.5 nm) of the silicon oxide film under the third conditions C3. This is because the pressure in the chamber 2 is so low that the amounts of the steam and the HF gas in the chamber 2 that are necessary for etching are reduced.

As understood from the description above, it is important to maintain the pressure in the chamber 2 to some extent and lower the temperature of the substrate W to etch the silicon oxide film with a larger etch amount and also at a higher selection ratio. For example, under the first conditions C1 and the second conditions C2, the pressure in the chamber 2 is 80 Torr, and only the temperature of the substrate W differs. Under the second conditions C2 including the lower temperature of the substrate W, the selection ratio and the etch rate of the silicon oxide film 20 are higher than those under the first conditions C1.

Here, while the pressure in the chamber 2 is maintained at 80 Torr, adopting 30° C. lower than that under the second conditions C2 as the temperature of the substrate W is considered (see the fifth conditions C5 in FIG. 4). However, since the saturated steam pressure at a temperature of 30° C. is approximately 30 Torr (see also FIG. 4), the pressure in the chamber 2 under the fifth conditions C5 becomes higher than the saturated steam pressure. Although the pressure (partial pressure) of the steam in the chamber 2 is lower than that in the chamber 2 (80 Torr), the pressure of the steam in the chamber 2 is probably higher than the saturated steam pressure (30 Torr) under the fifth conditions C5. Thus, the steam is probably liquefied and adhered to the surface of the substrate W. When the steam is liquefied, its surface tension probably causes the patterns formed on the surface of the substrate W to collapse.

In contrast, the pressure in the chamber 2 is lower than the saturated steam pressure under the first conditions C1 to the fourth conditions C4 (see FIG. 4). Thus, the probability that the steam is liquefied and adhered to the surface of the substrate W can be reduced under any one of the first conditions C1 to the fourth conditions C4. Ideally, liquefaction of the steam can be prevented. Consequently, under any one of the first conditions C1 to the fourth conditions C4, the probability that the liquefaction causes the patterns to collapse can be reduced, and a collapse of the patterns caused by the liquefaction can be ideally prevented.

As understood from the description above, the supply flow rates of the HF gas, the steam, and the nitrogen gas supplied to the chamber 2, the exhaust flow rate of the gas exhausted from the chamber 2, and the temperature of the substrate W are determined based on a selection ratio, an etch amount (an etch rate), and a saturated steam pressure of water. For example, the temperature of the substrate W is preferably lower than or equal to 50° C. in consideration of the selection ratio. In other words, the heating mechanism 5 preferably controls the temperature of the substrate W at 50° C. or less in the temperature control step (Step S5). In consideration of the selection ratio, the temperature of the substrate W is more preferably lower than or equal to 40° C., and much more preferably lower than or equal to 30° C.

Furthermore, the pressure in the chamber 2 is preferably lower than or equal to 80 Torr and lower than the saturated steam pressure, in consideration of liquefaction of the steam. In other words, the APC valve 9, the steam flow rate controller 13, the HF gas flow rate controller 14, and the nitrogen gas flow rate controller 15 control the exhaust flow rate, the supply flow rate of the steam, the supply flow rate of the HF gas, and the supply flow rate of the nitrogen gas, respectively, so that the pressure in the chamber 2 is lower than or equal to 80 Torr and lower than the saturated steam pressure.

The supply flow rates of the HF gas, the steam, and the nitrogen gas, the exhaust flow rate of the gas from the chamber 2, and the temperature of the substrate W may be preset, for example, by an experiment or in simulation. The controller 3 controls, in the etching of the substrate W, the heating mechanism 5, the APC valve 9, the steam flow rate controller 13, the HF gas flow rate controller 14, and the nitrogen gas flow rate controller 15, using these various amounts as target values. This can reduce the liquefaction of the steam, and etch the silicon oxide film 20 at a higher selection ratio.

In the example above, the steam starts to be supplied in the steam supplying step (Step S6) before start of supplying the HF gas in the HF gas supplying step (Step S7). Thus, the HF gas starts to be supplied to the chamber 2 while the steam has been supplied to the chamber 2. The first predetermined time from start of supplying the steam to start of supplying the HF gas may be set in a range, for example, approximately between 1 to 5 seconds.

If the HF gas is supplied without any steam in the chamber 2, an unintended non-target film (e.g., a silicon nitride film) may be etched by the HF gas. In contrast, first, steam is supplied to the chamber 2, and the HF gas is supplied after a lapse of the first predetermined time (e.g., 1 to 5 seconds) since start of supplying the steam in the example above. Thus, the probability of etching the non-target film can be reduced. In other words, the non-target film can be protected.

In the example above, the pressure in the chamber 2 has been set lower than the saturated steam pressure. Thus, the pressure (partial pressure) of the steam should be lower than the saturated steam pressure. Consequently, a designer may calculate the partial pressure of the steam, based on the supply flow rates of the HF gas, the steam, and the nitrogen gas and the pressure in the chamber 2, and set the supply flow rates, the exhaust flow rate, and the temperature so that the partial pressure of the steam is lower than the saturated steam pressure.

### Embodiment 2

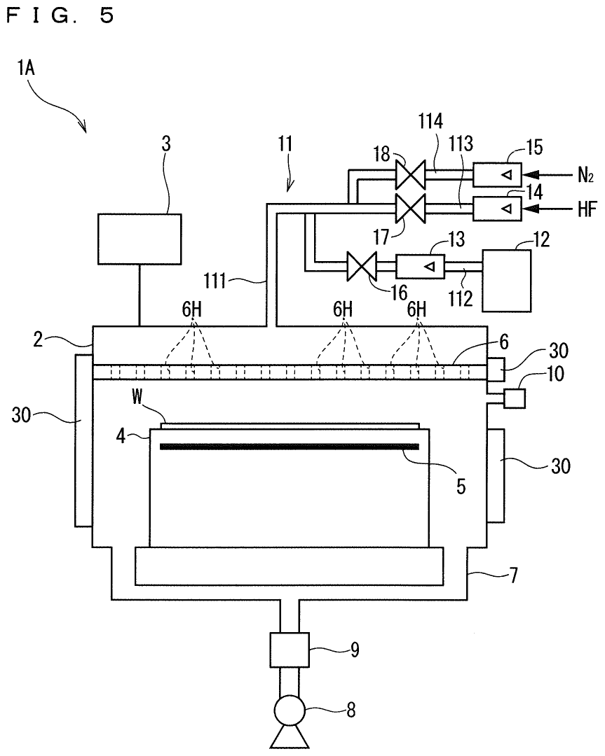

FIG. 5 schematically illustrates an example structure of an etching apparatus 1A. The etching apparatus 1A has the same structure as that of the etching apparatus 1 except for the presence or absence of a heating mechanism 30 for the chamber 2. The heating mechanism 30 heats the chamber 2. In the example of FIG. 5, the heating mechanism 30 is attached to the sidewall of the chamber 2. In a specific example, the heating mechanism 30 is attached all around the external wall surface of the sidewall of the chamber 2.

The heating mechanism 30 is, for example, a resistance-heated electric heater. The heating mechanism 30 may include, for example, a lamp instead of being an electric heater. The lamp may irradiate the chamber 2 with infrared rays to control the temperature of the chamber 2 at a predetermined temperature. Alternatively, the heating mechanism 30 may be a heat pump unit that exchanges heat between a heating medium and the chamber 2. The controller 3 controls the heating mechanism 30. The heating mechanism 30 increases the temperature of the chamber 2 to or above a boiling point of water. The heating mechanism 30 heats the chamber 2, for example, so that the temperature of the chamber 2 ranges from 100° C. to 200° C.

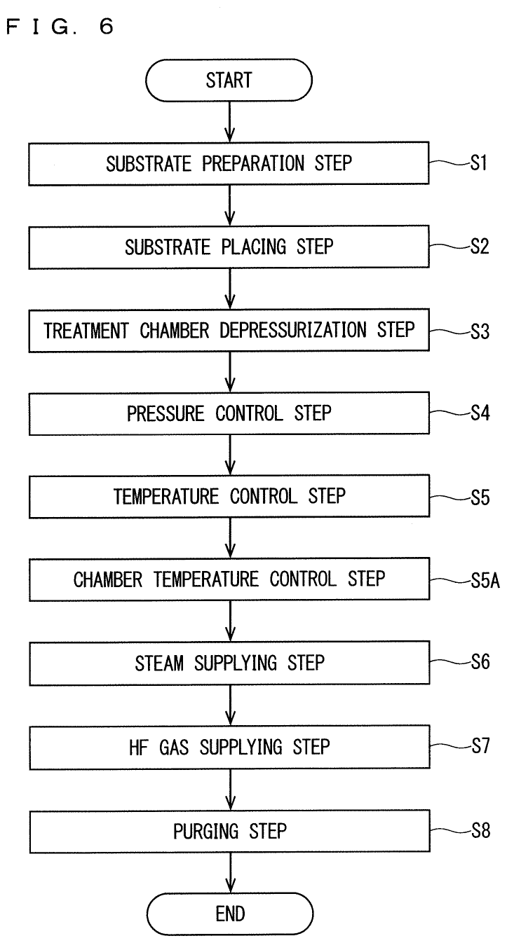

FIG. 6 is a flowchart illustrating example operations of the etching apparatus 1A. These operations include Step S5A which is performed in addition to the operations of the etching apparatus 1. Step S5A is performed, for example, between Steps S5 and S6. In Step S5A, the controller 3 controls the heating mechanism 30 so that the temperature of the chamber 2 is set higher than or equal to 100° C. (a chamber temperature control step). Specifically, the temperature of the chamber 2 is, for example, the temperature of the inner wall surface of the chamber 2. The controller 3 may start performing the chamber temperature control step (Step S5A) almost simultaneously with the pressure control step (Step S4).

This can reduce the probability that the steam is liquefied and adhered to the inner wall surface of the chamber 2. This also can reduce a probability of corrosion of the chamber 2.

Although the etching apparatuses 1 and 1A are described in detail, the description is in all aspects illustrative and does not restrict the etching apparatuses 1 and 1A. Therefore, numerous modifications and variations that have not yet been exemplified are devised without departing from the scope of this disclosure. The structures described in Embodiments and the modifications can be appropriately combined or omitted unless any contradiction occurs.

Although the target film is an oxide film in the examples above, the target film is not limited to this. The target film may be another film made of, for example, tungsten. In short, the target film may be any film to be etched using steam and the HF gas.

Although the nitrogen gas is supplied to the chamber 2 in the examples above, the gas to be supplied to the chamber 2 is not limited to this. The nitrogen gas may be replaced with an inert gas such as argon. This may apply to the carrier gas of steam.

While the invention has been shown and described in detail, the foregoing description is in all aspects illustrative and not restrictive. It is therefore understood that numerous modifications and variations can be devised without departing from the scope of the invention.

What is claimed is:

1. A method for etching a target film formed on a substrate, using steam and hydrogen fluoride gas, the method comprising:
a substrate placing step of placing the substrate in a chamber;
a steam supplying step of supplying the steam to the chamber; and
a hydrogen fluoride gas supplying step of supplying the hydrogen fluoride gas to the chamber,
wherein in the steam supplying step, a flow rate of the steam is controlled so that a pressure of the steam on a surface of the substrate is lower than a saturated steam pressure.

2. The method according to claim 1, further comprising:
a temperature control step of controlling a temperature of the substrate at 50° C. or less using a heating mechanism for the substrate; and
a pressure control step of controlling a pressure in the chamber at 80 Torr or less.

3. The method according to claim 1, further comprising
a chamber temperature control step of controlling a temperature of the chamber at 100° C. or more using a heating mechanism for the chamber.

4. The method according to claim 1,
wherein the steam starts to be supplied in the steam supplying step, before start of supplying the hydrogen fluoride gas in the hydrogen fluoride gas supplying step.
